(19) United States
(12) Patent Application Publication
(10) Pub. No.: US 2025/0182678 A1
(43) Pub. Date: Jun. 5, 2025

(54) DISPLAY DEVICE

(71) Applicant: SONY SEMICONDUCTOR SOLUTIONS CORPORATION, KANAGAWA (JP)

(72) Inventor: KAZUKI YOKOYAMA, KANAGAWA (JP)

(21) Appl. No.: 18/844,323

(22) PCT Filed: Jan. 20, 2023
(86) PCT No.: PCT/JP2023/001611

§ 371 Date: Sep. 5, 2024

(30) Foreign Application Priority Data
Mar. 18, 2022 (JP) 2022-044624

(51) Int. Cl. G09G 3/32; G09G 3/3233

(52) U.S. Cl. CPC G09G 3/32; G09G 3/3233; G09G 2320/066

(57) ABSTRACT

Visibility of a boundary at a screen end is suppressed. A display device includes a first pixel and a second pixel in a pixel array in which pixels are arranged in a two-dimensional array. The first pixel is arranged in a display area for displaying image information. The second pixel is arranged in a non-display area arranged in a peripheral area existing outside the display area. Furthermore, the second pixel can emit black color light, and the intensity of light to be emitted gradually decreases from the pixel arranged on the innermost circumference adjacent to the first pixel toward the pixel arranged on the outermost circumference opposite to the display area.

### TECHNICAL FIELD

The present disclosure relates to a display device.

### BACKGROUND ART

With an increase in technologies such as augmented reality (AR) and virtual reality (VR), it is required to enhance immersion feeling when these technologies are used. In order to enhance the immersive feeling, there is an increasing demand for a high-contrast device in which a frame is hardly visually recognized at an end of a light emitting region at the time of black luminance emission. Since a display using a light emitting element such as an organic light emitting diode (OLED) is a self-luminous device that does not use a backlight or the like, there is a tendency to realize a high contrast of 10,000:1 or more, but the light emission efficiency is increasing along with power saving and AR demand, and realization of a high contrast is being recognized as a problem.

However, even in a case where black luminance is output using an OLED or the like, light with the lowest luminance is often emitted, and there is a high probability that a boundary (frame) with a region where light is not actually emitted is visually recognized.

### CITATION LIST

### Patent Document

Patent Document 1: Japanese Patent Application Laid-Open No. 2018-106136

### SUMMARY OF THE INVENTION

### Problems to be Solved by the Invention

Therefore, the present disclosure provides a display device that suppresses visibility of a boundary at an end of a screen.

### Solutions to Problems

According to an embodiment, a display device includes a first pixel and a second pixel in a pixel array in which the pixels are arranged in a two-dimensional array. The first pixel is arranged in a display area for displaying image information. The second pixel is arranged in a non-display area arranged in a peripheral area existing outside the display area. Furthermore, the second pixel can emit black color light, and the intensity of light to be emitted gradually decreases from the pixel arranged on the innermost circumference adjacent to the first pixel toward the pixel arranged on the outermost circumference opposite to the display area.

A light emitting element of the second pixel arranged on an innermost circumference may emit light at a light emission intensity at which black color light is emitted in the first pixel, and
a light emitting element of the second pixel adjacent to the second pixel arranged on the innermost circumference on a side not adjacent to the first pixel may have an anode connected to an anode of a light emitting element of a second pixel arranged on the innermost circumference through a resistor.

The light emitting element of the second pixel may have an anode connected to an anode of a light emitting element of the second pixel adjacent on a side where the first pixel is arranged through a resistor.

The second pixel may include a non-light emitting pixel in which an anode of a light emitting element is open, and
the non-light emitting pixels may be arranged such that a ratio of the non-light emitting pixels increases toward an outer side from the second pixel arranged on the innermost circumference to the second pixel arranged on the outermost circumference.

A current flowing through the anode of the light emitting element may gradually decrease from the innermost circumference to the outermost circumference in the second pixel.

In the second pixel, a resistance value disposed between the anode of the light emitting element and a power supply voltage may gradually increase from the innermost circumference to the outermost circumference.

In the second pixel, an input power supply voltage may gradually decrease from the innermost circumference to the outermost circumference.

The second pixel may gradually reduce a current flowing through the anode of the light emitting element by changing a ratio of a capacitance provided in the pixel from the innermost circumference to the outermost circumference.

In the second pixel, transmittance of a color filter applied to a light emitting element in the pixel may decrease from the innermost circumference to the outermost circumference.

The color filter included in the second pixel may include a region overlapping the color filter of the adjacent second pixel, and the region where the color filters of the adjacent second pixels overlap each other may increase from the innermost circumference to the outermost circumference of the second pixel.

A width of a black matrix provided between the adjacent second pixels may gradually increase from the innermost circumference to the outermost circumference.

The second pixel may include a neutral density (ND) filter, and a light transmittance of the ND filter may decrease from the innermost circumference to the outermost circumference.

The second pixel may include a polarizing plate on an emission side of the light emitting element, and the polarizing plate may be disposed such that intensity of light emitted from the innermost circumference toward the outermost circumference decreases.

In the second pixel, an optical system in the pixel may be arranged such that light to be emitted decreases from the innermost circumference toward the outermost circumference.

In the second pixel, a thickness of a convex surface of a micro lens in the pixel provided on the light emission side of the light emitting element may decrease from the innermost circumference to the outermost circumference.

An optical system may be provided which diffuses light emitted from the first pixel located on the outermost circumference toward the outermost circumference side of the second pixel.

The second pixel disposed on the innermost circumference may emit black color light, and
the display device may further include an optical system that diffuses light emitted from the second pixel disposed on the innermost circumference toward the outermost circumference side.

### BRIEF DESCRIPTION OF DRAWINGS

FIG. 1 is a view schematically illustrating a display device according to an embodiment.

FIG. 2 is a diagram schematically illustrating a display area and a non-display area according to an embodiment.

FIG. 3 is a diagram illustrating an example of a pixel according to an embodiment.

FIG. 4 is a diagram illustrating an example of a pixel group according to an embodiment.

FIG. 5 is a diagram illustrating an example of a pixel group according to an embodiment.

FIG. 6 is a diagram illustrating an example of a pixel group according to an embodiment.

FIG. 7 is a diagram illustrating an example of a pixel group according to an embodiment.

FIG. 8 is a diagram illustrating an example of a pixel group according to an embodiment.

FIG. 9 is a diagram illustrating an example of a pixel group according to an embodiment.

FIG. 10 is a diagram illustrating an example of a pixel group according to an embodiment.

FIG. 11 is a diagram illustrating an example of a pixel group according to an embodiment.

FIG. 12 is a diagram illustrating an example of a pixel group according to an embodiment.

FIG. 13 is a diagram illustrating an example of a pixel group according to an embodiment.

FIG. 14 is a diagram illustrating an example of a pixel group according to an embodiment.

FIG. 15 is a diagram illustrating an example of a pixel group according to an embodiment.

FIG. 16 is a diagram illustrating an example of a pixel according to an embodiment.

FIG. 17 is a diagram illustrating an example of a pixel according to an embodiment.

FIG. 18 is a diagram illustrating an example of a pixel according to an embodiment.

FIG. 19 is a diagram illustrating an example of a pixel according to an embodiment.

FIG. 20 is a diagram illustrating an example of a pixel according to an embodiment.

FIG. 21 is a diagram illustrating an example of a pixel according to an embodiment.

FIG. 22A is a view illustrating an internal state of a vehicle from a rear side to a front side of a vehicle.

FIG. 22B is a view illustrating an internal state of the vehicle from an oblique rear to an oblique front of the vehicle.

FIG. 23A is a front view of a digital camera as a second application example of the electronic device.

FIG. 23B is a rear view of the digital camera.

FIG. 24A is an external view of an HMD which is a third application example of the electronic device.

FIG. 24B is an external view of a smart glass.

FIG. 25 is an external view of a TV which is a fourth application example of the electronic device.

FIG. 26 is an external view of a smartphone which is a fifth application example of the electronic device.

### MODE FOR CARRYING OUT THE INVENTION

The following is a description of embodiments of the present disclosure, with reference to the drawings. The drawings are used for explanation, and the shape and size of each configuration in actual devices, the ratios of size to other configurations, and the like are not necessarily as illustrated in the drawings. Further, since the drawings are illustrated in a simplified manner, it should be understood that components necessary for implementation other than those illustrated in the drawings are provided as appropriate.

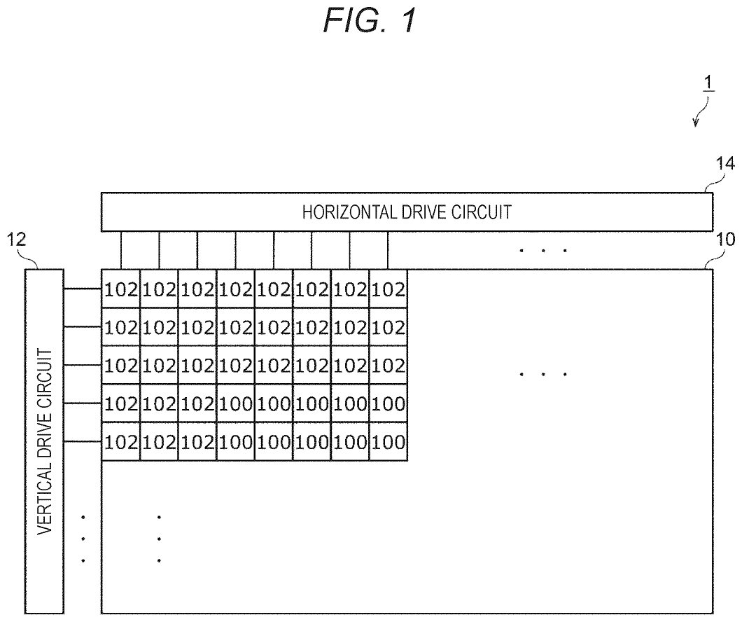

FIG. 1 is a diagram schematically illustrating a display device according to an embodiment. The display device 1 includes a pixel array 10, a vertical drive circuit 12, and a horizontal drive circuit 14. In addition, circuits such as a control circuit (not illustrated), a power supply circuit, and the like for supplying power necessary for display and controlling each circuit are appropriately provided as necessary.

The display device 1 may be, for example, a device such as a display, a monitor, a projector, or a head-mounted display. Furthermore, the display device 1 may be a device that executes display of a device such as a smartphone or a tablet terminal.

The pixel array 10 is a region indicating a display area. In the pixel array 10, pixels are arranged in a two-dimensional array. The pixel array 10 includes a display area for displaying a shadow image and a non-display area for not displaying a shadow image. First pixels 100 including a light emitting element that emits light on the basis of a display signal are arranged in the display area, and second pixels 102 that are not used to display the display signal are arranged in the non-display area.

The non-display area is arranged in a peripheral area outside the display area. For example, the second pixels 102 existing on the innermost circumference in the non-display area are arranged adjacent to (includes a line direction, a column direction, and an oblique direction) to the first pixels 100 existing on the outermost circumference in the display area.

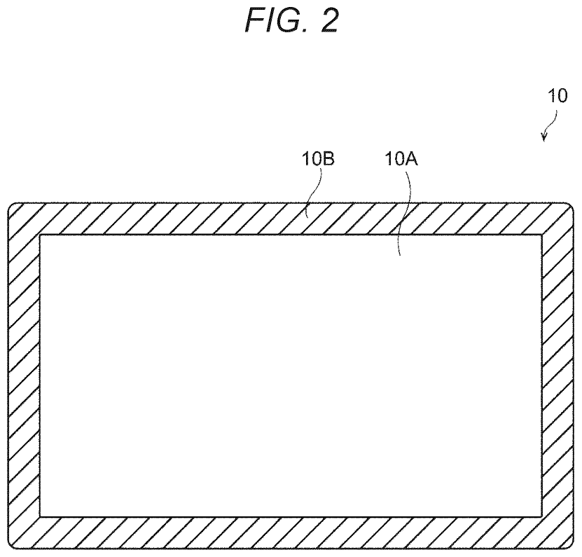

FIG. 2 is a diagram illustrating a display area and a non-display area according to an embodiment. In the pixel array 10, a region for displaying a shadow image of the central portion is defined as a display area 10A. On the other hand, a hatched area located outside the display area 10A is defined as a non-display area 10B. That is, the innermost second pixels 102 are arranged so as to be adjacent to the outermost first pixels 100.

Returning to FIG. 1, the first pixels 100 are pixels including general light emitting elements and pixel circuits. The light emitting element emits light according to the pixel value on the basis of the signal applied to the first pixel 100.

The second pixels 102 are pixels that have the same or substantially the same configuration as the first pixels 100 but are controlled not to emit light. The substantially same configuration includes the configurations shown in the respective embodiments of the present specification, and for example, refers to a circuit configuration in which at least one or a plurality of configurations or connection relationships in a pixel are different, such as a connection relationship between a light emitting element and a power supply voltage is different from that of the first pixel 100, but there is no large difference as a whole pixel. For example, in the second pixels 102, light emission is controlled such that the anode of the light emitting element is opened. The connection of the anode of the light emitting element will be described in each embodiment.

As an example, the second pixels 102 may be pixels capable of emitting black color light. The black color light emission is, for example, light emission that outputs a minimum pixel value that can be input, but is not limited thereto, and may be light emission that outputs a pixel value lower than a predetermined threshold. Furthermore, as another example, the black color light emission may be defined as light emission having a minimum intensity (or light emission having an intensity lower than a predetermined threshold value) in a state where the transistor in the pixel is driven.

That is, the second pixels 102 may be capable of outputting the darkest light in a case where the first pixels 100 are in an energized state. In the present disclosure, the second pixels 102 are caused to emit light to reduce a contrast difference between the display area and the other areas, thereby performing control such that the boundary is not visually recognized.

In order to cope with this, the pixel circuit of the second pixels 102 may be designed such that a light emission intensity gradually decreases from the innermost circumference, that is, the pixels adjacent to the first pixels 100 toward the outermost circumference, that is, the side opposite to the display area. In this context, the pixel circuit may be a broad concept including an optical system such as a lens provided on the light emitting element.

In a non-limiting example of FIG. 1, three second pixels 102 are provided in each of the line direction and the column direction around the outermost peripheral first pixel 100, but the present invention is not limited thereto. In addition, it is not necessary to provide the same number of second pixels 102 in the line direction and the column direction, and the number of second pixels 102 arranged in the line direction and the column direction may be different.

Note that, in both the first pixels 100 and the second pixels 102, the pixel may be provided with a color filter that emits light of a single color, and may emit light of a single color. As another example, the pixel may be divided into sub-pixels, provided with a color filter such as RGB (W), and configured to emit light of a mixed color. In addition, an infrared cut filter or the like may be provided.

The light emitting element provided in the pixel may be any element such as a light emitting diode (LED), an OLED, or an organic electro luminescence (OEL). In these elements, a cathode may be connected to a ground voltage, and light may be emitted by a current flowing from an anode. Furthermore, as another example, the pixel may change the light emission intensity by controlling the liquid crystal.

The vertical drive circuit 12 outputs a signal for selecting a line to emit light.

The horizontal drive circuit 14 drives pixels belonging to which column in the line selected by the vertical drive circuit 12 and outputs a signal for determining the pixel value.

Each pixel can emit light having an arbitrary pixel value on the basis of the drive signals output from the vertical drive circuit 12 and the horizontal drive circuit 14. Note that, for the second pixel 102, for example, a signal indicating the lowest pixel value such as R=G=B=0 may be output.

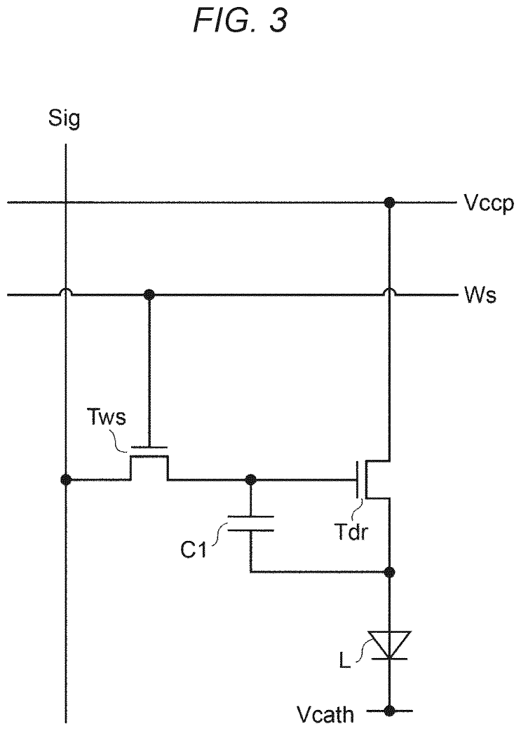

FIG. 3 is a diagram illustrating a non-limiting example of the configuration of the pixel. The pixel includes a light emitting element L. Furthermore, the pixel includes transistors Tws and Tdr and a capacitor C1.

As described above, the light emitting element L emits light when a current flows from the anode to the cathode. The cathode is connected to a reference voltage Vcath (for example, the ground voltage). An anode of the light emitting element L is connected to a source of a transistor Tdr and one terminal of the capacitor C1.

A transistor Tws is, for example, an n-type MOSFET, and is a transistor (writing transistor) that controls writing of a pixel value. In the transistor Tws, a data voltage indicating a pixel value is input to a drain from a signal line Sig, a source is connected to the other end of the capacitor C1 and a gate of the transistor Tds, and a control signal for write control is applied to a gate from the signal line Ws.

The transistor Tws writes the data voltage supplied from the signal line Sig to the capacitor C1 according to the control signal from the signal line Ws. When the transistor Tws is turned on, the capacitor C1 is charged (written) with the data voltage supplied from the signal line Sig, and the light emission intensity of the light emitting element L is controlled by the charge amount of the capacitor C1.

A transistor Tdr is, for example, an n-type MOSFET. The current based on the voltage indicating the pixel value written in the capacitor C1 by the transistor Tws flows to the light emitting element L by driving the transistor Tdr. The transistor Tdr has a drain connected to a voltage Vccp for driving the MOSFET, a source connected to the anode of the light emitting element L, and a gate connected to the drain of the transistor Tws.

Since the signal stored by the capacitor C1 is applied to the gate of the transistor Tdr, a source potential becomes a sufficiently large value, so that a drain current corresponding to this signal flows. When the drain current flows, the light emitting element L emits light with intensity (luminance) corresponding to the data voltage input to the pixel.

As a simple example, the pixel emits light with appropriate intensity by performing writing based on the data voltage input from the signal line Sig for determining the light emission intensity for each pixel in this manner and causing a drain current corresponding to the intensity of the written signal to flow to the light emitting element L.

Hereinafter, the pixel illustrated in FIG. 3 will be described as an example.

### First Embodiment

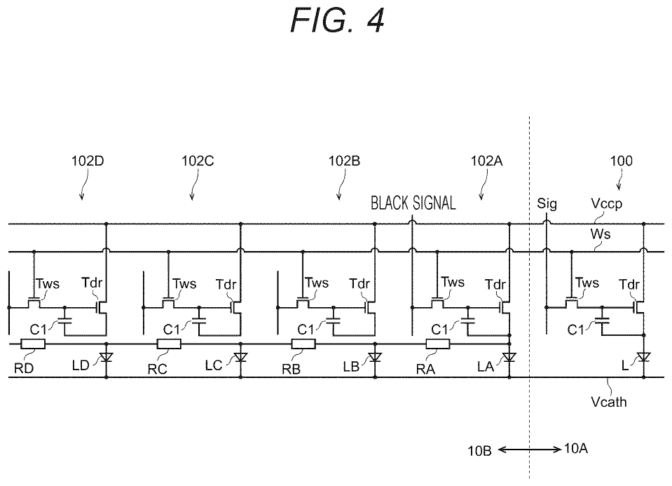

FIG. 4 is a diagram illustrating an example of a pixel group according to an embodiment. In this drawing, the outermost peripheral first pixel 100 and four second pixels 102A, 102B, 102C, and 102D connected thereto are illustrated.

The pixel illustrated on the rightmost side is the outermost peripheral first pixel 100. The first pixel 100 emits light corresponding to a value of the signal Sig from the light emitting element L. The outermost peripheral first pixel 100 configures a pixel at an edge of the display area 10A.

Similarly to the first pixel 100, the second pixel 102A has a path from a power supply voltage Vccp to the anode of the light emitting element. Therefore, when light emission is selected by the vertical drive circuit 12 and the horizontal drive circuit 14, the light emitting element LA emits light. As illustrated in the drawing, a data voltage that emits black color light may be input to the second pixel 102A through the horizontal drive circuit 14. As another example, a voltage corresponding to black color light emission may be constantly applied at the timing of display.

In the second pixel 102, anodes of the light emitting elements L are connected to each other through a resistor. For example, the anode of the light emitting element LB of the second pixel 102B is connected to the anode of the light emitting element LA of the second pixel 102 A through a resistor RA. Furthermore, the anode of the light emitting element LC of the second pixel 102C is connected to the anode of the light emitting element LB of the second pixel 102B through a resistor RB, and the anode of the light emitting element LD of the second pixel 102D is connected to the anode of the light emitting element LC of the second pixel 102C through a resistor RC.

On the other hand, the anodes of the light emitting elements LB, LC, and LD of the second pixels 102B, 102C, and 102D do not have a path connected to the power supply voltage Vccp in the pixel. With such connection, (light emission intensity of light emitting element LA)>(light emission intensity of light emitting element LB)>(light emission intensity of light emitting element LC)>(light emission intensity of light emitting element LD)> . . . is obtained by voltage drop due to each resistor.

The magnitude relationship among the resistances RA, RB, RC, and RD is not particularly limited, and may be any relationship that can be appropriately perceived as gradation by human eyes.

As described above, according to the present embodiment, the black color light emission is performed in the innermost circumference of the non-display area, and the light emission intensity is gradually decreased outward from the black color light emission, whereby the gradation is generated in the boundary area. As a result, a contrast difference at the boundary between the display area and the non-display area can be reduced, and the visibility of the boundary can be reduced.

Note that, in the above description, the anodes of the light emitting elements of different pixels in the column belonging to the same line are connected, but similar processing can be performed in the column direction of the display area. That is, a circuit in which the light emission intensity gradually decreases from the innermost second pixel 102 toward the outermost second pixel 102 can be similarly formed. In the example of the present embodiment, it can be realized by mounting the resistor between the anodes of the light emitting elements in the column direction.

Further, in the second pixels 102 arranged in a diagonal direction of the display area, the above-described implementation in the line direction and the column direction may also be performed. For example, the anode of the light emitting element of the second pixel 102 adjacent to the upper left of the display area may be connected to the anode of the light emitting element of the second pixel 102 adjacent to the right of the same line through the resistor.

The second pixel 102 positioned in such a column direction and a diagonal direction is not described in the following embodiment, but can be similarly mounted.

### Second Embodiment

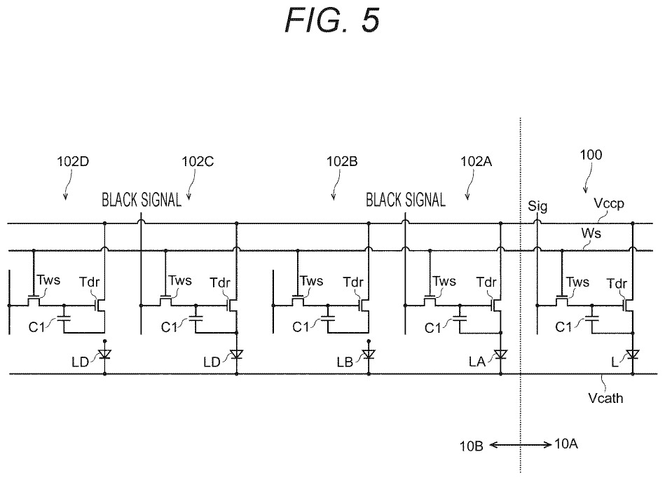

FIG. 5 is a diagram illustrating an example of a pixel group according to an embodiment. As illustrated in FIG. 5, in the second pixel 102, a pixel in which the anode of the light emitting element L is open may be appropriately arranged. The pixel in which the anode of the light emitting element L is not open may emit black color light.

Since the second pixel 102 in which the anode of the light emitting element L is open does not emit light, black is displayed in a strict sense. On the other hand, the second pixel 102 in which the light emitting element L is not open emits light in black. With the appropriate arrangement of the second pixel 102 that does not emit light and the second pixel 102 that emits black color light, gradation can be generated in a pseudo manner.

Note that, in the present embodiment, the anode of the light emitting element L is opened, but any connection point in the pixel may be opened so that the light emitting element L does not emit light (in black). That is, at least one of any connection existing between the pixel power supply on a positive side and the light emitting element L or the connection from the light emitting element L to the pixel power supply on a negative side may be disconnected.

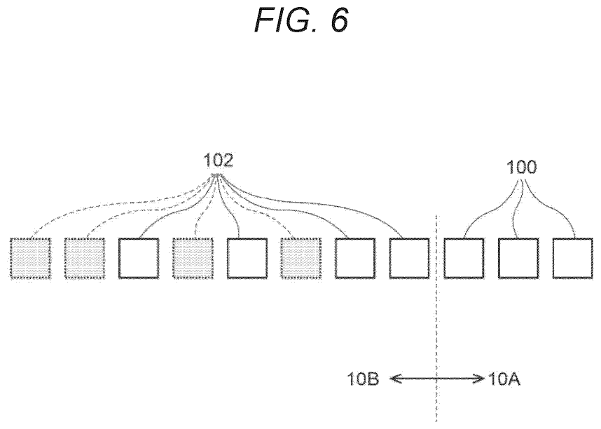

FIG. 6 is a diagram showing a non-limiting example of the arrangement of pixels that do not emit light and pixels that emit black color light. FIG. 6 illustrates the first pixels 100 and the second pixels 102 near a boundary between the display area 10A and the non-display area 10B. In a case where image information and video information are input, pixels indicated by a solid line are pixels that emit light, and pixels indicated by a dotted line are pixels that do not emit light (pixels whose anodes of the light emitting element are open).

As illustrated in FIG. 6, the second pixels 102 may be arranged such that the proportion of pixels that do not emit light gradually increases from the innermost second pixels 102 toward the outermost second pixels 102. By arranging in this way, a pseudo gradation occurs.

As described above, according to the present embodiment, black color light is emitted in the innermost circumference of the non-display area and the proportion of the second pixels 102 that do not emit light gradually increases outward from the black color light emission, so that gradation is generated in the boundary area in a pseudo manner. As a result, a contrast difference at the boundary between the display area and the non-display area can be reduced, and the visibility of the boundary can be reduced.

### Third Embodiment

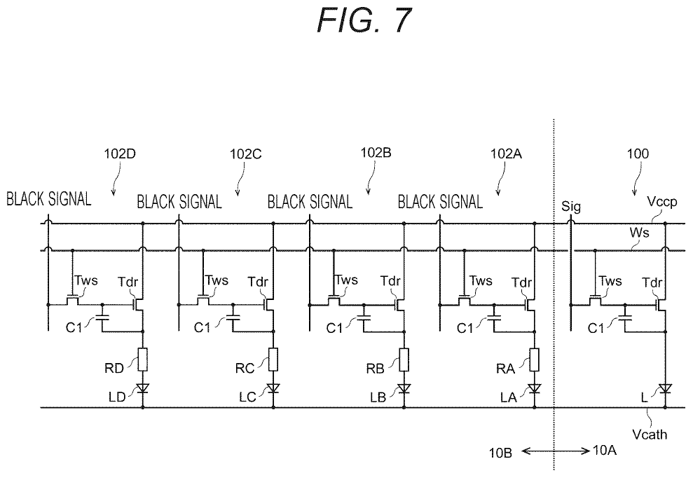

FIG. 7 is a diagram illustrating an example of a pixel group according to an embodiment. In the present embodiment, a current flowing through the anodes of the second pixels 102 is gradually and directly reduced from the innermost circumference to the outermost circumference.

Each of the second pixels 102 may include a resistor between a conductive wire that propagates a signal of the pixel value and the anode of the light emitting element L. In a non-limiting example of FIG. 7, a resistor is connected in series with the light emitting element L between the light emitting element L and the drain of the transistor Tdr, that is, between the light emitting element L and the conductive wire connected to the power supply voltage Vccp serving as a current source. As a specific example, as illustrated in the drawing, in the second pixel 102A, a resistor RA is connected to the anode of the light emitting element LA. In the second pixels 102B, 102C, and 102D, the resistors RB, RC, and RD are arranged at the anodes of the light emitting elements LB, LC, and LD, respectively.

Here, the resistance value is set as RA<RB<RC<RD. With a change in the resistance value in this manner, the intensity of black color light emission can be gradually decreased from the innermost circumference to the outermost circumference.

In the above description, the resistance value is changed, but instead of providing a resistor, implementation may be performed such that a width of the wiring connected to the anode of the light emitting element L becomes narrower toward the second pixel 102 on the outer side.

As described above, according to the present embodiment, the black color light emission is performed from the innermost circumference to the outermost circumference of the non-display area, but the black color light emission can be arranged such that the intensity gradually decreases from the innermost second pixel 102 to the outermost second pixel 102. As a result, a contrast difference at the boundary between the display area and the non-display area can be reduced, and the visibility of the boundary can be reduced.

### Fourth Embodiment

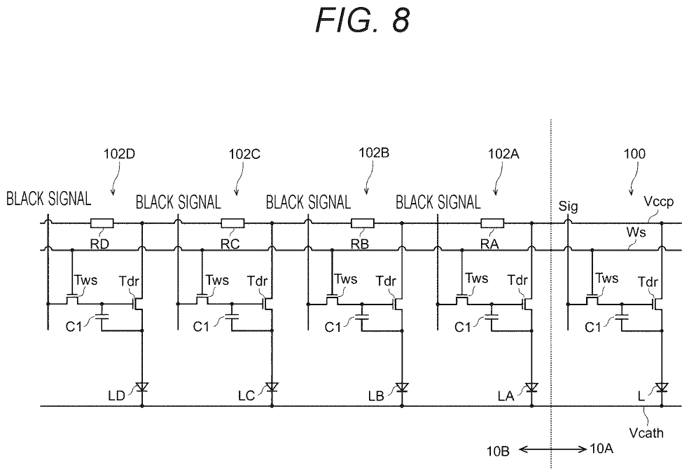

FIG. 8 is a diagram illustrating an example of a pixel group according to an embodiment. The second pixel 102 includes a resistor that causes a voltage drop in the path of the power supply voltage Vccp. This resistor is disposed such that the voltage applied to the anode of the light emitting element gradually decreases from the innermost circumference to the outermost circumference.

In the second pixel 102A, the same power supply voltage Vccp as that of the first pixel 100 and a transistor Tdr for driving the light emitting element LA are connected.

In the second pixel 102B, a voltage obtained by lowering the power supply voltage applied to the second pixel 102A by the resistor RA is applied.

In the second pixel 102C, a voltage obtained by lowering the power supply voltage applied to the second pixel 102B by the resistor RB is further applied.

The second pixel 102D is further applied with a voltage that is a voltage drop by the resistor RC with respect to a power supply voltage applied to the second pixel 102C.

In this manner, the power supply voltage applied to the second pixel 102 may be configured to gradually decrease from the innermost circumference to the outermost circumference. Note that, similarly to the above description, implementation may be performed by, for example, narrowing the width of the wiring of the power supply voltage, or the like, instead of explicitly including a resistor.

As described above, according to the present embodiment, the black color light emission is performed from the innermost circumference to the outermost circumference of the non-display area, but the black color light emission can be arranged such that the intensity gradually decreases from the innermost second pixel 102 to the outermost second pixel 102. As a result, a contrast difference at the boundary between the display area and the non-display area can be reduced, and the visibility of the boundary can be reduced.

Note that a resistor may be further provided between the first pixel 100 and the second pixel 102A.

### Fifth Embodiment

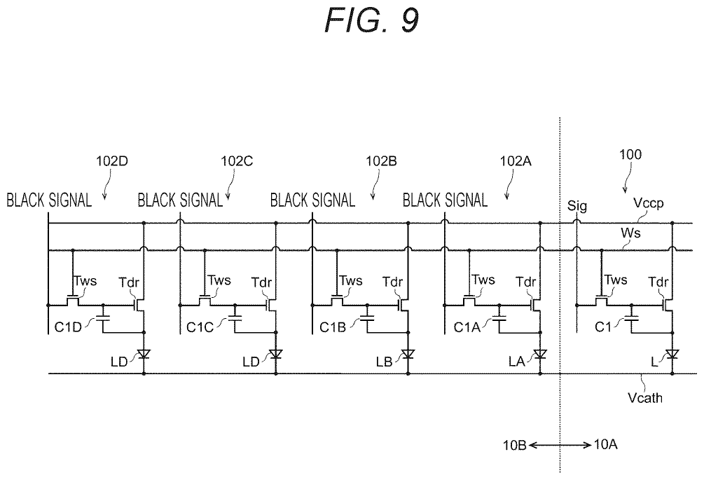

FIG. 9 is a diagram illustrating an example of a pixel group according to an embodiment. As illustrated in FIG. 9, the charge amount stored in the pixel may be changed to form gradation by changing the capacitance of the capacitor provided in the pixel.

The second pixel 102A includes a capacitor C1A. The second pixel 102B includes a capacitor C1B. The second pixel 102C includes a capacitor C1C. The second pixel 102D includes a capacitor C1D.

Capacitances of these capacitors have, for example, a relationship of C1A>C1B>C1C>C1D. With such a relationship, in a case where the same black signal is applied, the current flowing through the anode of the light emitting element can be gradually reduced from the inner circumference again to the outermost circumference.

As described above, according to the present embodiment, the black color light emission is performed from the innermost circumference to the outermost circumference of the non-display area, but the black color light emission can be arranged such that the intensity gradually decreases from the innermost second pixel 102 to the outermost second pixel 102. As a result, the contrast difference at the boundary between the display area and the non-display area can be reduced, and the visibility of the boundary can be reduced.

### Sixth Embodiment

FIG. 10 is a diagram illustrating an example of a pixel group according to an embodiment. In the present embodiment, the light emission intensity is adjusted by a color filter instead of controlling the current and voltage in the pixel circuit. FIG. 10 illustrates a color filter CF arranged on a display surface side of the light emitting element L in each pixel. A color bar illustrated in an upper part indicates the transmittance of visible light of the color filter CF provided for each light emitting element L illustrated in the lower part.

In this manner, the emission intensity of black may be controlled by reducing the light transmittance of the color filter from the innermost second pixel 102 toward the outermost second pixel 102. In the present embodiment, the second pixel 102 may be driven such that the light emitting elements L emit light of the same black color.

As a non-limiting example, the color filter can be implemented by changing the transmittance of a substance constituting the color filter.

As a non-limiting example, the color filter can be implemented by lengthening the transmission path of a substance configuring the color filter, that is, increasing a thickness of the color filter.

### Seventh Embodiment

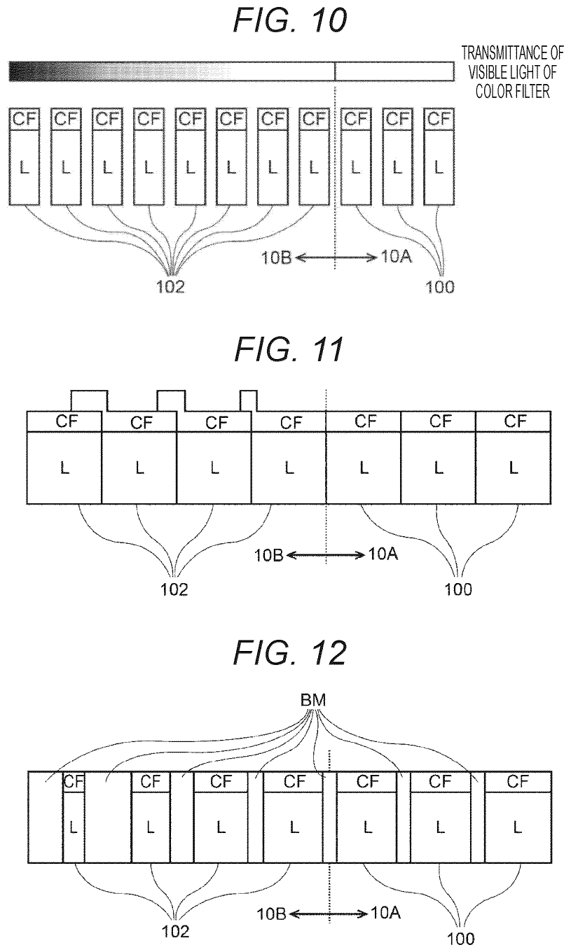

FIG. 11 is a diagram illustrating a configuration of a color filter as a non-limiting example. As illustrated in FIG. 11, in the manufacturing process, the color filters of second pixels 102 may be formed to overlap (have fogging). In a case where the light emission intensity is controlled in this manner, the light emission intensity can be adjusted in the same manner as described above by forming a color filter CF such that a region where the color filter CF overlaps gradually increases on the upper surface of the light emitting element L from the innermost second pixel 102 toward the outermost second pixel 102.

For example, in a case where R, G, and B filters are provided as the color filters, the transmittance of the superimposed region becomes substantially zero in these filters. Therefore, the transmittance of the overlapping region decreases, and the intensity of the black color light emission output from a light emitting element L decreases as the overlapping region increases on the upper surface of the light emitting element L.

In this example, the color filter has overlap for each pixel, but the present invention is not limited thereto. For example, a pixel may be divided into a plurality of sub-pixels, and a color filter may be arranged for each sub-pixel. In such a case, the light emission intensity can be adjusted by widening the overlapping region of the color filters in the pixel from the innermost second pixel 102 to the outermost second pixel 102.

Note that, in FIG. 11, the color filter CF is provided so as to be in contact with the light emitting element L, but the present invention is not limited to such a form. For example, an optical system such as a micro lens may be provided between the color filter CF and the light emitting element L.

### Eighth Embodiment

FIG. 12 is a diagram illustrating a configuration of a pixel as a non-limiting example. In general, a black matrix is provided between light-emitting pixels so that light from adjacent pixels does not enter.

As illustrated in FIG. 12, the thickness of black matrix BM between the pixels gradually increases from the innermost circumference to the outermost circumference of the second pixel 102, so that the light emission area of light emitting element L can be reduced, and the intensity of black color light emission can be adjusted.

In FIG. 12, the black matrix for the light emitting element L is illustrated, but the present invention is not limited thereto. For example, a width of the black matrix in the display area of the light emitting element L may be substantially constant, and the width of the black matrix as the boundary of the color filter CF may be changed.

### Ninth Embodiment

As a non-limiting example, a neutral density (ND) filter may be provided on the display surface side of the second pixel 102. The transmittance of the ND filter is provided so as to gradually decrease from the innermost circumference to the outermost circumference of the second pixel 102.

In the ND filter, depending on characteristics, the lower the transmittance, the lower the light transmittance. As a result, the second pixel 102 on the outer side can lower the intensity of black emission light.

Also, the ND filter may be replaced with a polarizing plate. In this case, the transmittance is adjusted by a polarization angle of the polarizing plate. For example, in a case where the polarizing plate is provided on the display surface of the display device 1, the polarization angle of the polarizing plate included in the second pixel 102 itself may be changed so that the polarization angle gradually approaches the direction of 90 degrees from the polarization angle of the polarizing plate included in the display surface from the innermost peripheral second pixel 102 toward the outermost peripheral second pixel 102.

Such a polarizing plate may be mounted by a diffraction grating formed on the display surface side of the light emitting element L.

### Tenth embodiment

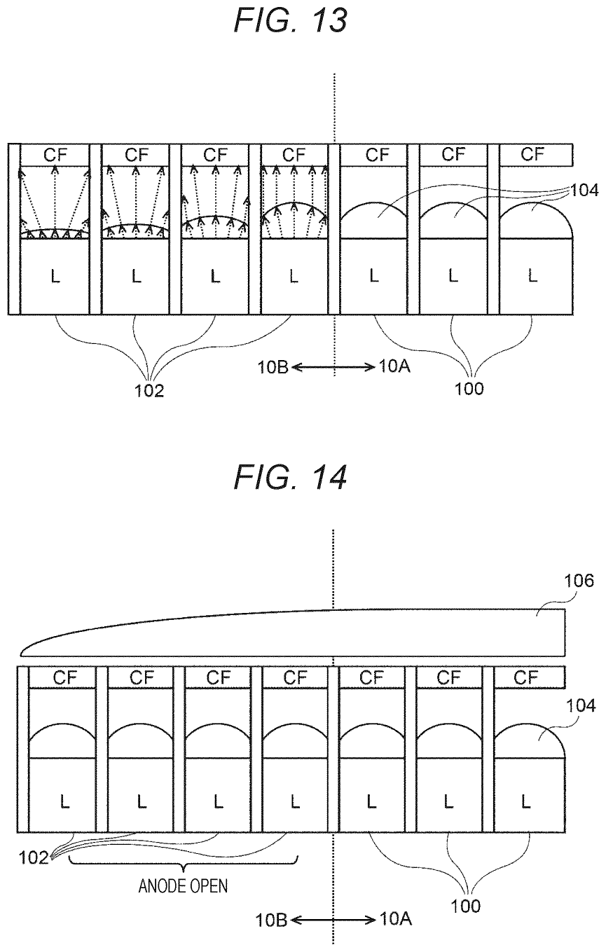

FIG. 13 is a diagram illustrating a configuration of a pixel as a non-limiting example. In the present embodiment, the emission intensity of black is controlled by adjusting an optical system between a light emitting element L and a color filter CF. That is, the optical system included in the second pixel 102 may be configured to gradually decrease the intensity of the emitted light from the innermost second pixel 102 toward the outermost second pixel 102.

As an example, the pixel includes a lens 104 on an upper surface of the light emitting element L. In the first pixel 100, the lens 104 refracts and diffracts the light appropriately emitted from the light emitting element L to the display surface side.

In the second pixel 102, the lens 104 is formed such that the thickness decreases from the innermost circumference to the outermost circumference, for example. The dotted line indicates what path the light emitted from the light emitting element L follows. With an arrangement of such a lens 104, the light emitted from the light emitting element L is not propagated to the display surface side toward the outside. As a result, the second pixel 102 on the outer side can lower the light emission intensity.

Note that the lens 104 may be a so-called normal lens as illustrated in FIG. 13, or may be a diffractive lens such as a Fresnel lens or a zone plate as another example.

According to the sixth embodiment to the tenth embodiment, the second pixel 102 emits black color light at the same level from the innermost circumference to the outermost circumference of the non-display area, but the light emission intensity can be gradually decreased from the innermost circumference to the outermost circumference by an optical system or the like that affects the display surface side of the light emitting element L. As a result, the contrast difference at the boundary between the display area and the non-display area can be reduced, and the visibility of the boundary can be reduced.

### Eleventh Embodiment

FIG. 14 is a diagram illustrating an example of a pixel group according to an embodiment. A lens 106 is provided on the display surface side of first pixels 100 and second pixels 102. The lens 106 is a lens that appropriately emits light output from each pixel to the display surface of the display device 1.

For example, the lens 106 may have a curved surface that refracts the light emitted from the first pixels 100 toward the outermost peripheral side of the second pixels 102 above the outermost peripheral first pixels 100. In a case where such a lens 106 is provided, all the second pixels 102 may be in a state in which the anodes of the light emitting elements L are open, that is, in a state of not emitting light.

As another example, the innermost second pixels 102 may emit black color light, and the black color light may be refracted toward the outermost second pixels 102. In this case, the anodes of the innermost second pixels 102 are appropriately connected to a power supply voltage through a drive circuit.

The lens may be another optical system that appropriately refracts or diffracts light.

As described above, according to the present embodiment, the black color light emission is performed from the innermost circumference to the outermost circumference of the non-display area, but the black color light emission can be arranged such that the intensity gradually decreases from the innermost second pixel 102 to the outermost second pixel 102. As a result, a contrast difference at the boundary between the display area and the non-display area can be reduced, and the visibility of the boundary can be reduced.

### Twelfth Embodiment

As described above, pixels may be divided into subpixels, and a color filter may be provided in each subpixel. In the present embodiment, as an example, a case where R, G, and B color filters are provided in subpixels will be described. Note that the present embodiment can be similarly applied to the aspects of each of the above-described embodiments.

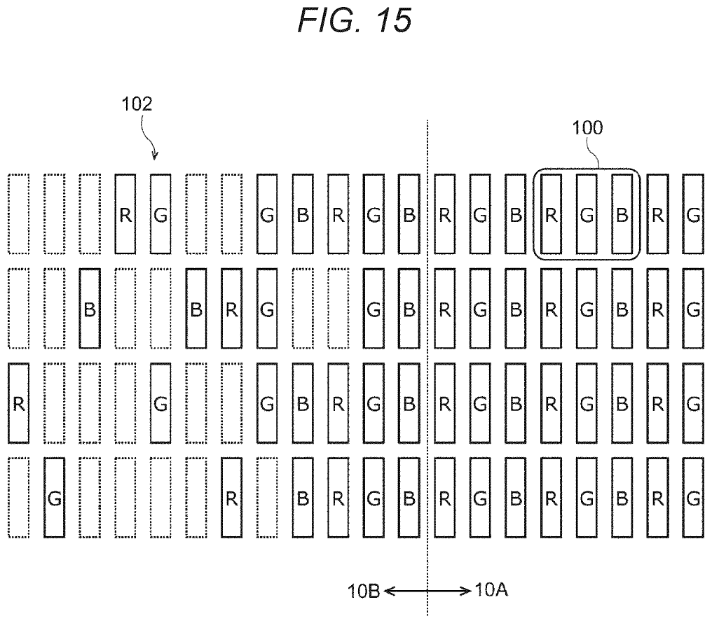

FIG. 15 is a diagram illustrating an example of a pixel group according to an embodiment. For example, as illustrated in the upper right, the pixel includes subpixels that emit R, G, and B light. Without limited to this, there may be W pixels, and the arrangement is not limited to the drawing.

Subpixels indicated by a dotted line in the non-display area 10B are subpixels in which the anodes of the light emitting elements are open. Human eyes easily acquire luminance information. For this reason, the emission of G having the spectrum in the luminance information tends to be easily perceived. The contribution to brightness is generally G>R>B.

Focusing on this, in the present embodiment, the connection of the anode may be opened so that the luminance component does not become higher than the inside toward from the innermost circumference to the outermost circumference. FIG. 15 illustrates an example, and the present invention is not limited to this arrangement.

As described above, according to the present embodiment, the black color light emission is performed from the innermost circumference to the outermost circumference of the non-display area, but the black color light emission can be arranged such that the intensity gradually decreases from the innermost second pixel 102 to the outermost second pixel 102. As a result, a contrast difference at the boundary between the display area and the non-display area can be reduced, and the visibility of the boundary can be reduced.

Note that, as in the above-described embodiment, at least one portion of the connection between the light emitting element L and the power supply voltage on the positive side or the negative side is disconnected, so that the current does not flow through the light emitting element L, whereby the same control can be performed.

Next, some examples of the configuration of the pixel other than FIG. 3 will be described.

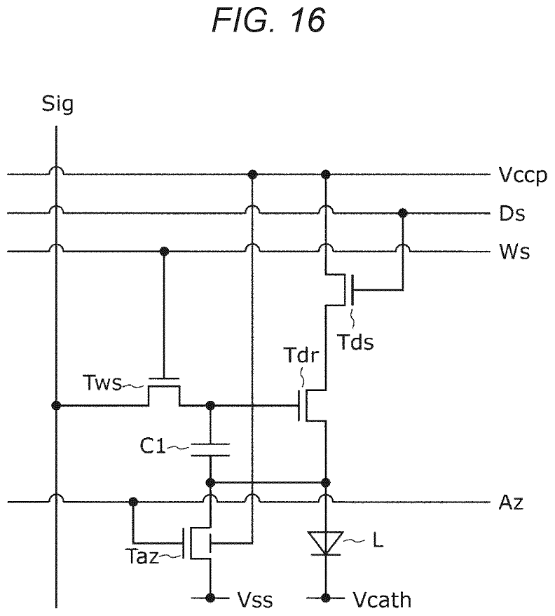

FIG. 16 is a diagram illustrating another example of the pixel circuit. As a general simple example, the pixel may include a transistor Taz, a transistor Tws, a transistor Tds, a transistor Tdr, and a capacitor C1.

The anode of the light emitting element L is connected to a drain of the transistor Taz, a source of the transistor Tdr, and one terminal of the capacitor C1.

The transistor Taz is, for example, an n-type MOSFET, and has a drain connected to the anode of the light emitting element L, a source connected to the voltage Vss, and a gate to which a reset voltage is applied from a signal line Az. The transistor Taz is a transistor that initializes a potential of the anode of the light emitting element L according to a reset voltage applied through the signal line Az. The voltage Vss is, for example, a reference voltage at the power supply voltage, and may represent a grounded state or may be a potential of 0 V.

The capacitor C1 is a capacitor for controlling the potential on the anode side of the light emitting element L.

The transistor Tws is, for example, an n-type MOSFET, and is a transistor that controls writing of a pixel value. In the transistor Tws, a data voltage indicating a pixel value is input to a drain from the signal line Sig, a source is connected to the other end of the capacitor C1 and a gate of the transistor Tdr, and a control signal for write control is applied to a gate from the signal line Ws.

The transistor Tws writes a data voltage supplied from the signal line Sig to the capacitor C1 according to a control signal from the signal line Ws. When the transistor Tws is turned on, the capacitor C1 is charged (written) with the data voltage supplied from the signal line Sig, and the light emission intensity of the light emitting element L is controlled by the charge amount of the capacitor C1.

The transistor Tds is, for example, an n-type MOSFET, and is a transistor that controls driving of causing a current based on a potential corresponding to a written pixel value to flow through the light emitting element L. The transistor Tds has a drain connected to the power supply voltage Vccp for driving the MOSFET, a source connected to the drain of the transistor Tdr, and a gate to which a drive signal for controlling the potential of the drain of the transistor Tdr is applied from the signal line Ds. According to the signal applied from the signal line Ds, the transistor Tds causes a drain current to flow, and increases the drain potential of the transistor Tdr.

A transistor Tdr is, for example, an n-type MOSFET. The current based on the voltage indicating the pixel value written in the capacitor C1 by the transistor Tws flows to the light emitting element L by driving the transistor Tdr. The transistor Tdr has a drain connected to the source of the transistor Tds, a source connected to the anode of the light emitting element L, and a gate connected to the drain of the transistor Tws.

Since the signal stored by the capacitor C1 is applied to the gate of the transistor Tdr, a source potential becomes a sufficiently large value, so that a drain current corresponding to this signal flows. When the drain current flows, the light emitting element L emits light with intensity (luminance) corresponding to the data voltage input to the pixel.

Similarly to the above, as a simple example, the pixel emits light by performing writing based on the data voltage input from the signal line Sig for determining the light emission intensity for each pixel in this manner and causing a drain current to flow in the light emitting element L according to the intensity of the written signal.

A transistor that performs a quick discharge operation at a timing after light emission and initializes a written state is the transistor Taz. A body of the transistor Taz needs to be held at a sufficiently large potential during operation (light emission, quenching) of the pixel for appropriate driving, and for example, the power supply voltage Vccp is applied.

In the present disclosure, for example, the anode of the light emitting element L may be appropriately opened. In the following example, similarly, it is assumed that the anode is appropriately opened in the second pixel 102 unless otherwise specified.

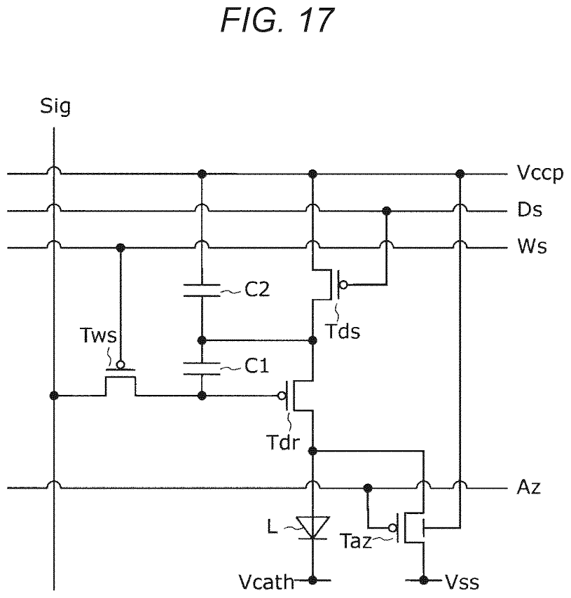

FIG. 17 is a diagram illustrating another example of the pixel. In FIG. 16, the configuration includes four transistors and one capacitor, but in FIG. 17, the pixel includes four transistors and two capacitors.

The capacitor C2 is a capacitor for charging a voltage corresponding to the signal Sig on the basis of the write signal Ws together with the capacitor C1. As described above, even when the number of capacitors is changed, the potential of the anode of the light emitting element L is controlled by the transistor Taz, so that the light is appropriately quenched and emitted.

In the above-described fifth embodiment, the luminance is controlled by the capacitance of the capacitor C1. However, in a case where two capacitors are provided as illustrated in FIG. 17, the luminance can also be controlled by changing the ratio of the capacitances of the respective capacitors.

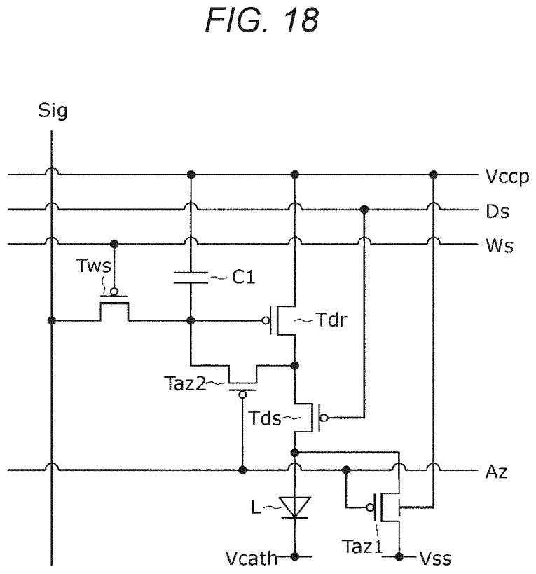

FIG. 18 is a diagram illustrating another example of the pixel. In FIG. 18, the pixel includes transistors Taz1 and Taz2 as transistors that control initialization of the anode potential of the light emitting element L. Also in such a mode, a voltage similar to that in each mode described above is applied to the transistor Taz1. In addition, application of a similar voltage to the transistor Taz2 may be controlled at the same timing.

The transistor Taz2 is a switch for resetting the charge charged in the capacitor C1. With this switch, the capacitor C1 can appropriately discharge before charging is started.

Even in such a mode, the optical system for the light emitting element L or the path from the power supply voltage Vccp can be operated in the similar manner as in each of the above-described embodiments.

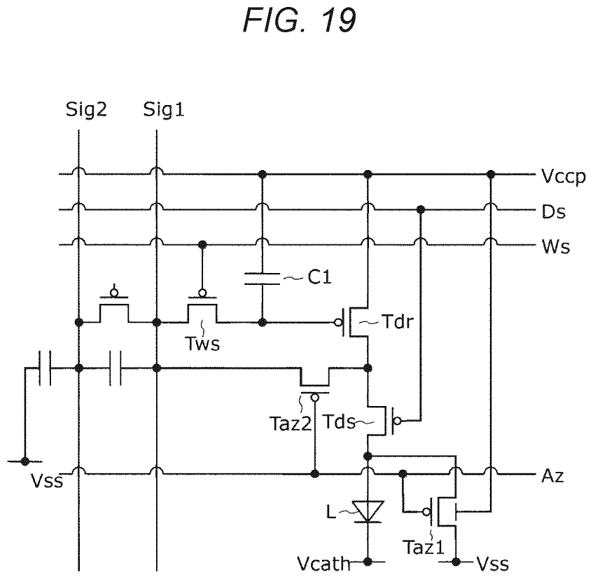

FIG. 19 is a diagram illustrating another example of the pixel. As illustrated in FIG. 19, even in a case where there are two signal lines, Sig1 and Sig2, propagating the data signal indicating the intensity of the pixel, the optical system for the light emitting element L or the path from the power supply voltage Vccp can be operated in the similar manner as in each of the above-described embodiments.

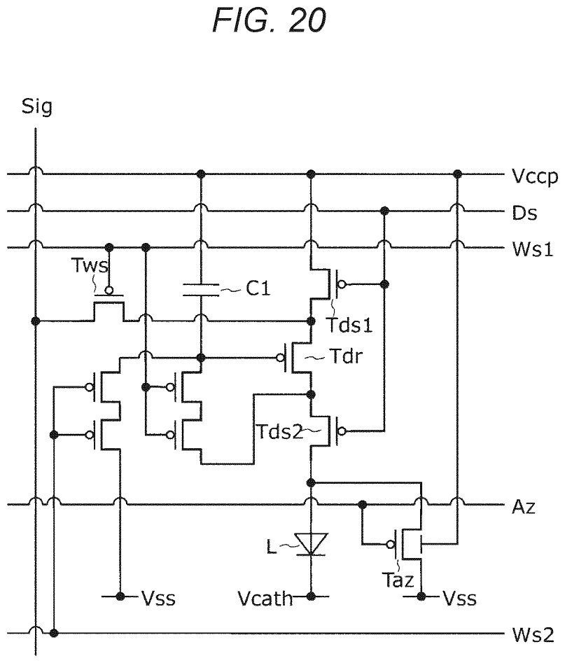

FIG. 20 is a diagram illustrating another example of the pixel. This pixel is connected to, in addition to the signal line Ws1 that propagates the voltage for performing the write control on the pixel, the signal line Ws2 that propagates the voltage for performing the write control on the previous line scanned first, and is controlled with the signal input from the signal line Ws2 as an offset. In such a mode that depends on control by another line, the present disclosure can also be appropriately applied. Furthermore, in this pixel, in order to stabilize charging, a write transistor that uses an offset and assists the transistor Tws is provided.

Even in such a mode, the optical system for the light emitting element L or the path from the power supply voltage Vccp can be operated in the similar manner as in each of the above-described embodiments.

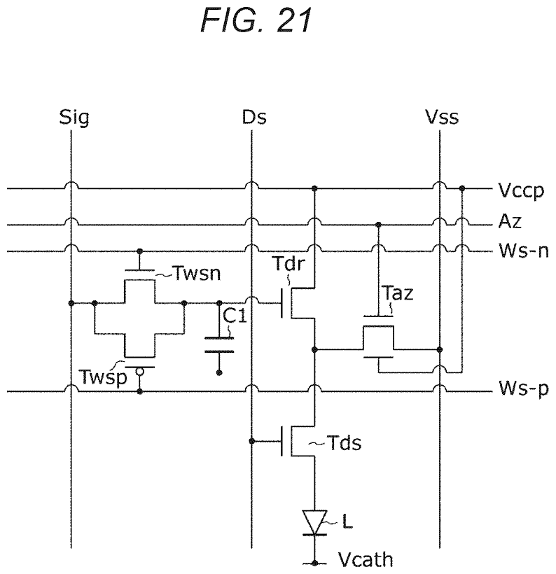

FIG. 21 is a diagram illustrating another example of the pixel. This pixel is configured to include transistors Tws_n and Tws_p instead of the transistor Tws in each of the above-described examples in order to control Ws complementarily. In such a configuration, control according to the present disclosure can also be adopted.

Note that, in the above description, only the main part of the present disclosure is illustrated for appropriate components such as other circuits necessary for display, but the pixels of the display device 1 appropriately include components (not illustrated) necessary for displaying video and the like in addition to the main part.

In addition, whether each transistor in the above is an n-type transistor or a p-type transistor is illustrated, but these transistors are illustrated as non-limiting examples, and the polarity of the transistor is not particularly limited as long as the transistor operates appropriately.

### APPLICATION EXAMPLES OF THE DISPLAY DEVICE 1 ACCORDING TO THE PRESENT DISCLOSURE

### First Application Example

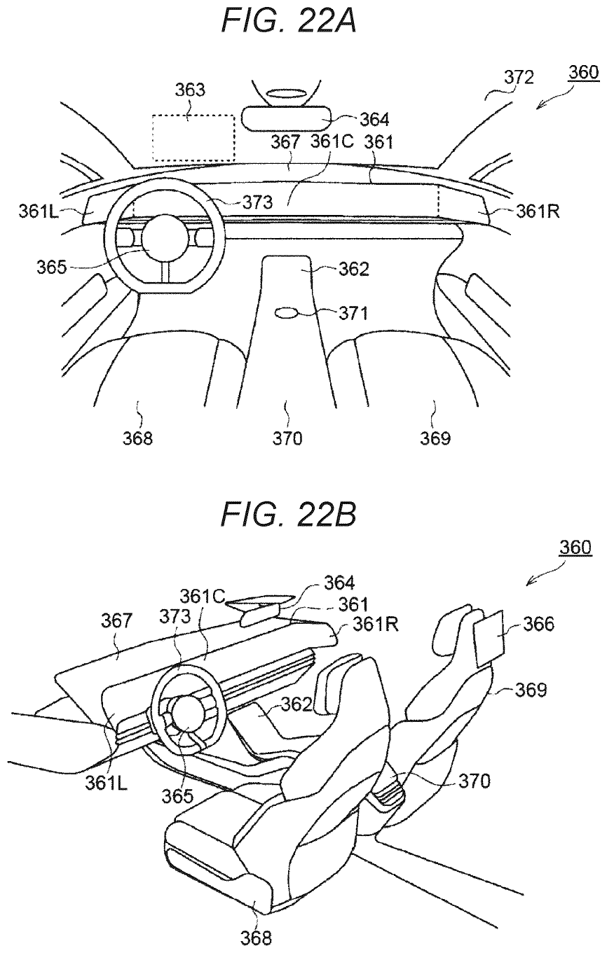

The display device 1 according to the present disclosure can be used for various applications. FIGS. 22A and 22B are views illustrating an internal configuration of a vehicle 360 as a first application example of the display device 1 according to the present disclosure. FIG. 22A is a diagram illustrating an internal state of the vehicle 360 as viewed from a rear side to a front side of the vehicle 360, and FIG. 22B is a diagram illustrating an internal state of the vehicle 360 as viewed from an oblique rear side to an oblique front side of the vehicle 360.

The vehicle 360 in FIGS. 22A and 22B includes a center display 361, a console display 362, a head-up display 363, a digital rear mirror 364, a steering wheel display 365, and a rear entertainment display 366.

The center display 361 is disposed on a dashboard 367 at a location facing a driver's seat 368 and a passenger seat 369. FIG. 22 illustrates an example of the center display 361 having a horizontally long shape extending from the driver seat 368 side to the passenger seat 369 side, but any screen size and arrangement location of the center display 361 may be adopted. The center display 361 can display information sensed by various sensors. As a specific example, the center display 361 can display an image captured by an image sensor, an image of the distance to an obstacle in front of or on a side of the vehicle, the distance being measured by a ToF sensor, a passenger's body temperature detected by an infrared sensor, and the like. The center display 361 can be used to display, for example, at least one piece of safety-related information, operation-related information, a lifelog, health-related information, authentication/identification-related information, or entertainment-related information.

The safety-related information is information of doze sensing, looking-away sensing, sensing of mischief of a child riding together, presence or absence of wearing of a seat belt, sensing of leaving of an occupant, and the like, and is information sensed by the sensor arranged to overlap with a back surface side of the center display 361, for example. The operation-related information senses a gesture related to an operation by an occupant, using a sensor. Gestures to be sensed may include an operation of various kinds of equipment in the vehicle 360. For example, operations of air conditioning equipment, a navigation device, an AV device, a lighting device, and the like are detected. The lifelogs include lifelogs of all the occupants. For example, the life log includes an action record of each occupant in the vehicle. By acquiring and storing the life log, it is possible to check a state of the occupant at a time of an accident. In the health-related information, the health condition of the occupant is estimated on the basis of the body temperature of the occupant detected by using a temperature sensor. Alternatively, the face of the occupant may be imaged by using an image sensor, and the health condition of the occupant may be estimated from the imaged facial expression. Further, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 362 can be used to display lifelog information, for example. The console display 362 is disposed near a shift lever 371 of a center console 370 between the driver's seat 368 and the passenger seat 369. The console display 362 can also display information detected by various sensors. Furthermore, the console display 362 may display an image of the surroundings of the vehicle captured with an image sensor, or may display an image of the distance to an obstacle in the surroundings of the vehicle.

The head-up display 363 is virtually displayed behind a windshield 372 in front of the driver's seat 368. The head-up display 363 can be used to display at least one piece of the safety-related information, the operation-related information, the lifelog, the health-related information, the authentication/identification-related information, or the entertainment-related information, for example. Being virtually disposed in front of the driver's seat 368 in many cases, the head-up display 363 is suitable for displaying information directly related to operations of the vehicle 360, such as the speed, the remaining amount of fuel (battery), and the like of the vehicle 360.

The digital rear mirror 364 can not only display the rear of the vehicle 360 but also display the state of an occupant in the rear seat, and thus, can be used to display the lifelog information by disposing a sensor on the back surface side of the digital rear mirror 364 in an overlapping manner, for example.

The steering wheel display 365 is disposed near the center of a steering wheel 373 of the vehicle 360. The steering wheel display 365 can be used to display at least one piece of the safety-related information, the operation-related information, the lifelog, the health-related information, the authentication/identification-related information, or the entertainment-related information, for example. In particular, being located close to the driver's hands, the steering wheel display 365 is suitable for displaying the lifelog information such as the body temperature of the driver, or for displaying information regarding operations of the AV device, the air conditioning equipment, or the like.

The rear entertainment display 366 is attached to the back side of the driver's seat 368 or the passenger seat 369, and is an occupant in the rear seat to enjoy viewing/listening. The rear entertainment display 366 can be used to display at least one piece of the safety-related information, the operation-related information, the lifelog, the health-related information, the authentication/identification-related information, or the entertainment-related information, for example. In particular, as the rear entertainment display 366 is located in front of the occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

As described above, disposing a sensor on the back surface side of the display device 1 makes it possible to measure the distance to an object existing in the surroundings. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. The display device 1 according to the present disclosure can be used in distance measurement by any of these methods. With a sensor disposed on the back surface side of the display device 1 according to the present disclosure in an overlapping manner, distance measurement of the passive type or the active type described above can be performed.

### Second Application Example

The display device 1 according to the present disclosure can be applied not only to various displays used in vehicles but also to displays mounted on various electronic apparatuses.

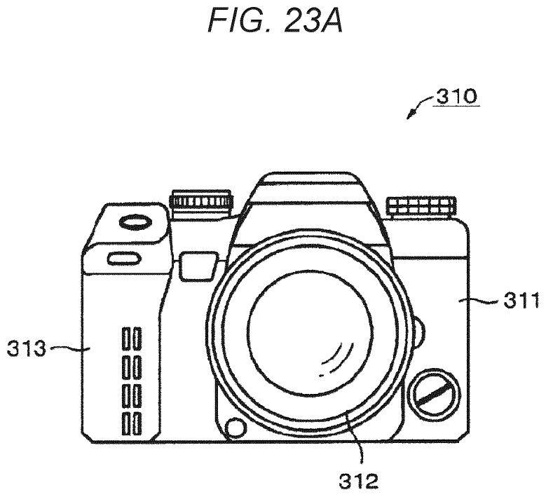

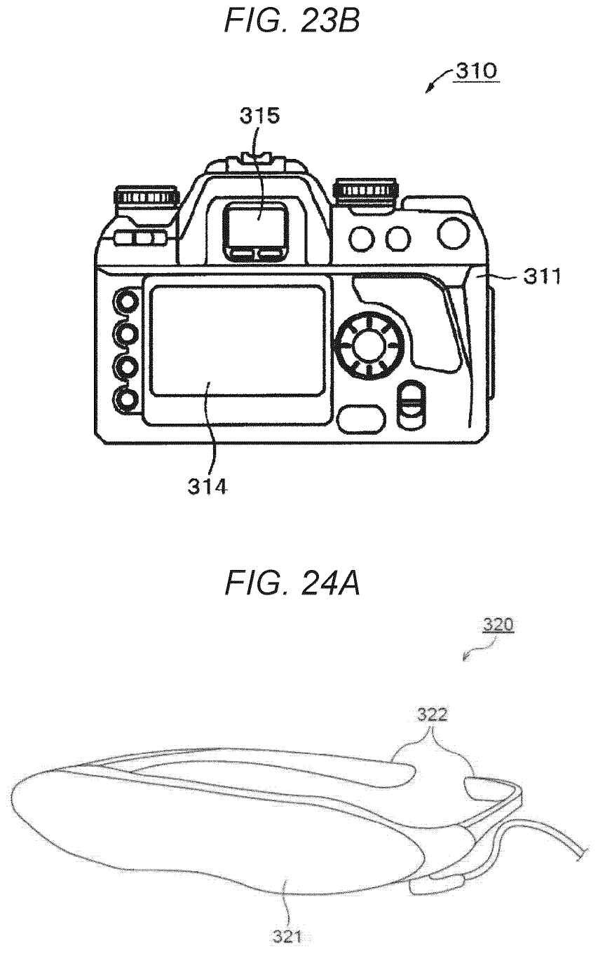

FIG. 23A is a front view of a digital camera 310 as a second application example of the display device 1. FIG. 23B is a rear view of the digital camera 310. The digital camera 310 in FIGS. 23A and 23B is an example of a single-lens reflex camera in which a lens 312 is replaceable, but is also applicable to a camera in which the lens 312 is not replaceable.

In the camera in FIGS. 23A and 23B, when a person who captures an image looks into an electronic viewfinder 315 to determine a composition while holding a grip 313 of a camera body 311, and presses a shutter while adjusting focus, captured image data is stored in a memory in the camera. As illustrated in FIG. 23B, on a back side of the camera, a monitor screen 316 that displays the captured image data and the like and a live image and the like, and the electronic viewfinder 315 are provided. Furthermore, there is a case where a sub screen that displays setting information such as a shutter speed and an exposure value is provided on the upper surface of the camera.

By disposing a sensor, in an overlapping manner, on the back surface side of the monitor screen 316, the electronic viewfinder 315, the sub screen, and the like that are used for the camera, the camera can be used as the display device 1 according to the present disclosure.

### Third Application Example

The display device 1 according to the present disclosure can also be applied to a head-mounted display (hereinafter referred to as an HMD). An HMD can be used for VR, AR, mixed reality (MR), substitutional reality (SR), or the like.

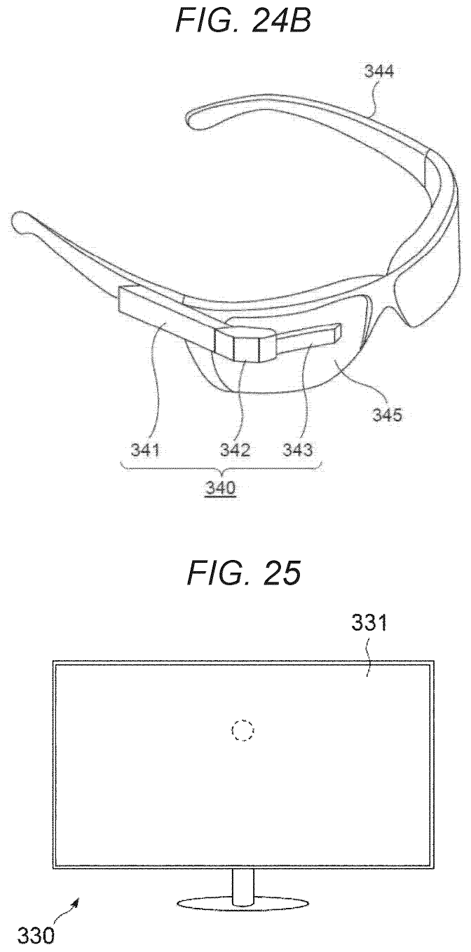

FIG. 24A is an external view of an HMD 320 as a third application example of the display device 1. The HMD 320 in FIG. 24A includes a mounting member 322 for attachment to cover human eyes. The attachment members 322 are hooked and secured to human ears, for example. A display device 321 is provided inside the HMD 320, and the wearer of the HMD 320 can visually recognize a stereoscopic image and the like with the display device 321. The HMD 320 includes a wireless communication function and an acceleration sensor, for example, and can switch stereoscopic images or the like displayed on the display device 321 in accordance with a posture, a gesture, or the like of the wearer.

Furthermore, a camera may be disposed in the HMD 320 to capture an image around the wearer, and an image obtained by combining the image captured by the camera with an image generated by a computer may be displayed on the display device 321. For example, the camera is disposed to overlap with the back surface side of the display device 321 visually recognized by the wearer of the HMD 320, an image of the surroundings of the eyes of the wearer is captured with the camera, and the captured image is displayed on another display provided on the outer surface of the HMD 320, so that a person around the wearer can recognize the expression of the face and the movement of the eyes of the wearer in real time.

Note that various kinds of HMD 320 are conceivable. For example, as illustrated in FIG. 24B, the display device 1 according to the present disclosure can also be applied to smart glasses 340 that display various kinds of information on glasses 344. The smart glasses 340 in FIG. 24B includes a main body portion 341, an arm portion 342, and a lens barrel portion 343. The main body portion 341 is connected to the arm portion 342. The main body portion 341 is detachable from the glasses 344. The main body portion 341 includes a display unit and a control board for controlling operations of the smart glasses 340. The main body portion 341 and the lens barrel are connected to each other through the arm portion 342. The lens barrel portion 343 emits image light emitted from the main body portion 341 through the arm portion 342, to the side of lenses 345 of the glasses 344. This image light enters the human eyes through the lenses 345. The wearer of the smart glasses 340 in FIG. 24B can visually recognize not only a surrounding situation but also various pieces of information emitted from the lens barrel portion 343, as with conventional glasses.

### Fourth Application Example

The display device 1 according to the present disclosure can also be applied to a television device (hereinafter referred to as a TV). In a today's TV, the frame tends to be as small as small, from the viewpoint of downsizing and design. Therefore, in a case where a camera to capture an image of a viewer is disposed on a TV, it is desirable to disposed the camera so as to overlap with the back surface side of a display panel 331 of the TV.

FIG. 25 is an external view of a TV 330 as a fourth application example of the display device 1. In the TV 330 in FIG. 25, the frame is minimized, and almost the entire region on the front side is the display area. The TV 330 includes a sensor such as a camera to capture an image of the viewer. The sensor in FIG. 25 is arranged on the back side of a part (for example, a broken line part) in the display panel 331. The sensor may be an image sensor module, or various sensors can be used such as a sensor for face authentication, a sensor for distance measurement, and a temperature sensor. A plurality of kinds of sensors may be disposed on the back surface side of the display panel 331 of the TV 330.

As described above, with the display device 1 of the present disclosure, an image sensor module can be disposed to overlap with the back surface side of the display panel 331. Accordingly, there is no need to dispose a camera or the like on the frame, the TV 330 can be downsized, and there is no possibility that the design is impaired by the frame.

### Fifth Application Example

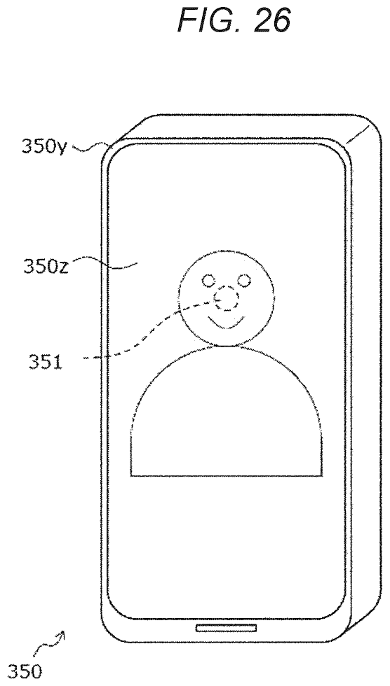

The display device 1 according to the present disclosure can also be applied to a smartphone and a mobile phone. FIG. 26 is an external view of a smartphone 350 as a fifth application example of the display device 1. In an example in FIG. 26, a display surface 350z covers nearly the outer shape size of the display device 1, and the width of a bezel 350y around the display surface 350z is set to several millimeters or smaller. In general, a front camera is often mounted on the bezel 350y, but in FIG. 26, as indicated by a broken line, the image sensor module 351 serving as the front camera is arranged on, for example, the back surface side of a substantially central portion of the display surface 2z. As the front camera is disposed on the back surface side of the display surface 2z in this manner, there is no need to disposed the front camera on the bezel 350y, and thus, the width of the bezel 350y can be narrowed.

Note that a plurality of the above-described embodiments may be applied within an applicable range.

The embodiments described above may have the following modes.
(1)

A display device, including:
in a pixel array in which pixels are arranged in a two-dimensional array, a first pixel arranged in a display area in which image information is displayed; and
a second pixel arranged in a non-display area arranged in a peripheral area existing outside the display area, in which
the second pixel enables black color light emission, and
the second pixel gradually decreases intensity of light to be emitted from a pixel disposed on an innermost circumference adjacent to the first pixel toward a pixel disposed on an outermost circumference opposite to the display area.
(2)

The display device according to (1), in which
a light emitting element of the second pixel arranged on an innermost circumference emits light at a light emission intensity at which black color light is emitted in the first pixel, and
a light emitting element of the second pixel adjacent to the second pixel arranged on the innermost circumference on a side not adjacent to the first pixel has an anode connected to an anode of a light emitting element of a second pixel arranged on the innermost circumference through a resistor.
(3)

The display device according to (2), in which
the light emitting element of the second pixel has an anode connected to an anode of a light emitting element of the second pixel adjacent on a side where the first pixel is arranged through a resistor.
(4)

The display device according to (1), in which
the second pixel includes a non-light emitting pixel in which an anode of a light emitting element is open, and
the non-light emitting pixels are arranged such that a ratio of the non-light emitting pixels increases toward an outer side from the second pixel arranged on the innermost circumference to the second pixel arranged on the outermost circumference.
(5)

The display device according to (1), in which
a current flowing through the anode of the light emitting element gradually decreases from the innermost circumference to the outermost circumference in the second pixel.
(6)

The display device according to (5), in which
in the second pixel, a resistance value disposed between the anode of the light emitting element and a power supply voltage gradually increases from the innermost circumference to the outermost circumference.
(7)

The display device according to (5), in which
in the second pixel, an input power supply voltage gradually decreases from the innermost circumference to the outermost circumference.
(8)

The display device according to (1), in which
the second pixel gradually reduces a current flowing through the anode of the light emitting element by changing a ratio of a capacitance provided in the pixel from the innermost circumference to the outermost circumference.
(9)

The display device according to any one of (1) to (8), in which in the second pixel, transmittance of a color filter applied to a light emitting element in the pixel decreases from the innermost circumference to the outermost circumference.
(10)

The display device according to (9), in which
the color filter included in the second pixel includes a region overlapping the color filter of the adjacent second pixel, and the region where the color filters of the adjacent second pixels overlap each other increases from the innermost circumference to the outermost circumference of the second pixel.
(11)

The display device according to any one of (1) to (8), in which a width of a black matrix provided between the adjacent second pixels gradually increases from the innermost circumference to the outermost circumference.
(12)

The display device according to any one of (1) to (8), in which
the second pixel includes a neutral density (ND) filter, and
a light transmittance of the ND filter decreases from the innermost circumference to the outermost circumference.
(13)

The display device according to any one of (1) to (8), in which
the second pixel includes a polarizing plate on an emission side of the light emitting element, and
the polarizing plate is disposed such that intensity of light emitted from the innermost circumference toward the outermost circumference decreases.
(14)

The display device according to any one of (1) to (12), in which
in the second pixel, an optical system in the pixel is arranged such that light to be emitted decreases from the innermost circumference toward the outermost circumference.
(15)

The display device according to (14), in which
in the second pixel, a thickness of a convex surface of a micro lens in the pixel provided on the light emission side of the light emitting element decreases from the innermost circumference to the outermost circumference.
(16)

The display device according to any one of (1) to (15), further including an optical system that diffuses light emitted from the first pixel located on the outermost circumference toward the outermost circumference side of the second pixel.
(17)

The display device according to any one of (1) to (15), in which
the second pixel disposed on the innermost circumference emits black color light, and the display device further comprises an optical system that diffuses light emitted from the second pixel disposed on the innermost circumference toward the outermost circumference side.

Aspects of the present disclosure are not limited to the above-described embodiments, and include various conceivable modifications. The effects of the present disclosure are not limited to the above-described contents. The components in each of the embodiments may be appropriately combined and applied. That is, various additions, modifications, and partial deletions can be made without departing from the conceptual idea and gist of the present disclosure derived from the contents defined in the claims and equivalents and the like thereof.

### REFERENCE SIGNS LIST

1 DISPLAY DEVICE
10 Pixel array
100 First pixel
102 Second pixel
104 Lens
106 Lens
12 Vertical drive circuit
14 Horizontal drive circuit

1. A display device, comprising:
in a pixel array in which pixels are arranged in a two-dimensional array, a first pixel arranged in a display area in which image information is displayed; and
a second pixel arranged in a non-display area arranged in a peripheral area existing outside the display area, wherein
the second pixel enables black color light emission, and
the second pixel gradually decreases intensity of light to be emitted from a pixel disposed on an innermost circumference adjacent to the first pixel toward a pixel disposed on an outermost circumference opposite to the display area.

2. The display device according to claim 1, wherein
a light emitting element of the second pixel arranged on an innermost circumference emits light at a light emission intensity at which black color light is emitted in the first pixel, and
a light emitting element of the second pixel adjacent to the second pixel arranged on the innermost circumference on a side not adjacent to the first pixel has an anode connected to an anode of a light emitting element of a second pixel arranged on the innermost circumference through a resistor.

3. The display device according to claim 2, wherein
the light emitting element of the second pixel has an anode connected to an anode of a light emitting element of the second pixel adjacent on a side where the first pixel is arranged through a resistor.

4. The display device according to claim 1, wherein
the second pixel includes a non-light emitting pixel in which an anode of a light emitting element is open, and
the non-light emitting pixels are arranged such that a ratio of the non-light emitting pixels increases toward an outer side from the second pixel arranged on the innermost circumference to the second pixel arranged on the outermost circumference.

5. The display device according to claim 1, wherein
in the second pixel, a current flowing through the anode of the light emitting element gradually decreases from the innermost circumference to the outermost circumference.

6. The display device according to claim 5, wherein
in the second pixel, a resistance value disposed between the anode of the light emitting element and a power supply voltage gradually increases from the innermost circumference to the outermost circumference.

7. The display device according to claim 5, wherein
in the second pixel, an input power supply voltage gradually decreases from the innermost circumference to the outermost circumference.

8. The display device according to claim 1, wherein
the second pixel gradually reduces a current flowing through the anode of the light emitting element by changing a ratio of a capacitance provided in the pixel from the innermost circumference to the outermost circumference.

9. The display device according to claim 1, wherein
in the second pixel, transmittance of a color filter applied to a light emitting element in the pixel decreases from the innermost circumference to the outermost circumference.

10. The display device according to claim 9, wherein
the color filter included in the second pixel includes a region overlapping the color filter of the adjacent second pixel, and the region where the color filters of the adjacent second pixels overlap each other increases from the innermost circumference to the outermost circumference of the second pixel.

11. The display device according to claim 1, wherein
a width of a black matrix provided between the adjacent second pixels gradually increases from the innermost circumference to the outermost circumference.

12. The display device according to claim 1, wherein
the second pixel includes a neutral density (ND) filter, and
a light transmittance of the ND filter decreases from the innermost circumference to the outermost circumference.

13. The display device according to claim 1, wherein
the second pixel includes a polarizing plate on an emission side of the light emitting element, and
the polarizing plate is disposed such that intensity of light emitted from the innermost circumference toward the outermost circumference decreases.

14. The display device according to claim 1, wherein
in the second pixel, an optical system in the pixel is arranged such that light to be emitted decreases from the innermost circumference toward the outermost circumference.

15. The display device according to claim 14, wherein
in the second pixel, a thickness of a convex surface of a micro lens in the pixel provided on the light emission side of the light emitting element decreases from the innermost circumference to the outermost circumference.

16. The display device according to claim 1, further comprising an optical system that diffuses light emitted from the first pixel located on the outermost circumference toward the outermost circumference side of the second pixel.

17. The display device according to claim 1, wherein
the second pixel disposed on the innermost circumference emits black color light, and
the display device further comprises an optical system that diffuses light emitted from the second pixel disposed on the innermost circumference toward the outermost circumference side.
